(19) United States
(12) Patent Application Publication
(10) Pub. No.: US 2015/0287367 A1
(43) Pub. Date: Oct. 8, 2015

(54) CHARGE RECYCLING DRIVER OUTPUT STAGE

(71) Applicant: QUALCOMM MEMS Technologies, Inc., San Diego, CA (US)

(72) Inventors: Wilhelmus Johannes Robertus Van Lier, San Diego, CA (US); Edward Keat Leem Chan, San Diego, CA (US); Vincent Anthony Condito, Santa Clara, CA (US)

(73) Assignee: QUALCOMM MEMS Technologies, Inc., San Diego, CA (US)

(21) Appl. No.: 14/245,878

(22) Filed: Apr. 4, 2014

(51) Int. Cl. G09G 3/34; H03F 3/45

(52) U.S. Cl. CPC G09G 3/3466; H03F 3/45076; H03F 2200/504; H03F 2203/45116; G09G 2310/0291

(57) ABSTRACT

This disclosure provides systems, methods and apparatus for recycling charge. In one aspect, a circuit may include amplifiers with power supplies provided by a capacitor voltage divider. A storage capacitor may be configured to be coupled one at a time and in parallel with individual capacitors of the voltage divider. The storage capacitor may store charge that may be reused.

### TECHNICAL FIELD

This disclosure relates to electromechanical systems and devices. More specifically, the disclosure relates to recycling charge in a driver output stage for an electromechanical system device, such as an interferometric modulator (IMOD).

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

In some implementations, one of the plates, or movable element, may be positioned based on an application of voltages to one or more electrodes of the IMOD. The voltages to be applied to the one or more electrodes of the IMOD may be provided by a driver circuit. In an implementation, the driver circuit's output stage may recycle charge.

### SUMMARY

The systems, methods and devices of this disclosure each have several innovative aspects, no single one of which is solely responsible for the desirable attributes disclosed herein.

One innovative aspect of the subject matter described in this disclosure can be implemented in a circuit for driving an electrode of a display unit. The circuit may include a first amplifier. An output of the first amplifier may be coupled with a first terminal of a first switch, the output of the first amplifier capable of providing a voltage in a first voltage range. The first amplifier may have a high power supply input associated with a first voltage source and a low power supply input associated with a second voltage source. The circuit may also include a second amplifier. An output of the second amplifier may be coupled with a first terminal of a second switch, the output of the second amplifier capable of providing a voltage in a second voltage range different from the first voltage range. A second terminal of the first switch may be coupled with a second terminal of the second switch, the second amplifier having a high power supply input associated with the second voltage source and a low power supply input associated with a third voltage source.

In some implementations, the first and second amplifiers may be operational amplifiers.

In some implementations, the circuit may include a capacitor voltage divider including a plurality of capacitors coupled in series to define nodes. The nodes may be capable of providing the first, second, and third voltage sources for the first amplifier and the second amplifier, respectively.

In some implementations, the capacitor voltage divider may include a first capacitor having a first terminal coupled with a first voltage input to define a first node. The first node may be capable of providing the first voltage source.

In some implementations, the circuit may also include a storage capacitor coupled in parallel with one of the plurality of capacitors in the capacitor voltage divider.

In some implementations, the first voltage source may be configured to provide a higher voltage than the second voltage source.

In some implementations, the second voltage source may be configured to provide a higher voltage than the third voltage source.

In some implementations, a highest voltage of the second voltage range may be less than a lowest voltage of the first voltage range.

In some implementations, a voltage difference between voltages capable of being provided by the first voltage source and the second voltage source may be equal to a voltage difference between voltages capable of being provided by the second voltage source and the third voltage source.

In some implementations, the first amplifier may have a first input. The output of the first amplifier may be coupled with the first input of the first amplifier, and the second amplifier may have a first input, the output of the second amplifier coupled with the first input of the second amplifier.

In some implementations, the circuit may include a third amplifier. An output of the third amplifier may be coupled with a first terminal of a third switch. The output of the third amplifier may be capable of providing a voltage in a third voltage range, the third amplifier having a high power supply input associated with a fourth voltage source and a low power supply input associated with a fifth voltage source. A second terminal of the third switch may be coupled with the second terminal of the first switch and the second switch.

In some implementations, the second voltage source may be capable of providing a lower voltage than the fourth voltage source.

Another innovative aspect of the subject matter described in this disclosure can be implemented in a system for biasing an electrode of a display unit. The system may include an output stage including a plurality of amplifiers. Each amplifier may have a high power supply input and a low power supply input. The system may also include a charge recycling circuit including a capacitor voltage divider. The capacitor voltage divider may include a plurality of capacitors coupled in series to define nodes. The nodes may be capable of providing voltage sources for the high power supply inputs and the low power supply inputs of the amplifiers.

In some implementations, the plurality of amplifiers in the output stage may include a first amplifier. An output of the first amplifier may be coupled with a first terminal of a first switch. The output of the first amplifier may be capable of providing a voltage in a first voltage range. The first amplifier may have a high power supply input associated with a first voltage source and a low power supply input associated with a second voltage source. The plurality of amplifiers may also include a second amplifier. An output of the second amplifier may be coupled with a first terminal of a second switch. The output of the second amplifier may be capable of providing a voltage in a second voltage range different from the first voltage range. A second terminal of the first switch may be coupled with a second terminal of the second switch. The second amplifier may have a high power supply input associated with the second voltage source and a low power supply input associated with a third voltage source.

In some implementations, the system may include a storage capacitor coupled in parallel with one of the plurality of capacitors in the capacitor voltage divider.

Another innovative aspect of the subject matter described in this disclosure can be implemented in a method for recycling charge. The method may include providing voltage sources for power supplies of a plurality of amplifiers. The plurality of amplifiers may include a first amplifier. An output of the first amplifier may be coupled with a first terminal of a first switch. The output of the first amplifier may be capable of providing a voltage in a first voltage range. The first amplifier may have a high power supply input associated with a first voltage source and a low power supply input associated with a second voltage source. The plurality of amplifiers may include a second amplifier. An output of the second amplifier may be coupled with a first terminal of a second switch. The output of the second amplifier may be capable of providing a voltage in a second voltage range different from the first voltage range. A second terminal of the first switch may be coupled with a second terminal of the second switch, the second amplifier having a high power supply input associated with the second voltage source and a low power supply input associated with a third voltage source. The method may include sinking current to a low power supply of one of the plurality of amplifiers. The method may also include transferring excess charge on the low power supply to a storage capacitor.

In some implementations, the method may include providing a capacitor voltage divider including a plurality of capacitors coupled in series to define nodes. The nodes may provide the voltage sources for the first amplifier and the second amplifier.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays, organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIG. 3 is a graph illustrating movable reflective layer position versus applied voltage for an IMOD display element.

FIG. 4 is a table illustrating various states of an IMOD display element when various common and segment voltages are applied.

FIG. 5A is an illustration of a frame of display data in a three element by three element array of IMOD display elements displaying an image.

FIG. 5B is a timing diagram for common and segment signals that may be used to write data to the display elements illustrated in FIG. 5A.

FIGS. 6A and 6B are schematic exploded partial perspective views of a portion of an electromechanical systems (EMS) package including an array of EMS elements and a backplate.

FIG. 7 is an example of a system block diagram illustrating an electronic device incorporating an IMOD-based display.

FIG. 8 is a circuit schematic of an example of a three-terminal IMOD.

FIG. 9A is an example of a system block diagram illustrating an output stage of a driver circuit.

FIG. 9B is an example of a system block diagram illustrating an output stage of a driver circuit with charge recycling.

FIG. 10A is a circuit schematic of an example of an output stage of a driver circuit.

FIG. 10B is a circuit schematic of an example of a charge recycling circuit for the output stage of FIG. 10A.

FIGS. 10C and 10D are circuit schematics of examples of simplified representations of the charge recycling circuit in FIG. 10B.

FIG. 11A is a circuit schematic of an example of an output stage of a driver circuit.

FIG. 11B is a circuit schematic of an example of a charge recycling circuit for the output stage of FIG. 11A.

FIG. 12A is a simplified illustration of power supplies for an output stage of a driver circuit with four amplifiers.

FIG. 12B is a simplified circuit schematic of a capacitor voltage divider of a charge recycling circuit for the output stage of FIG. 12A.

FIG. 13A is a simplified illustration of power supplies for an output stage of a driver circuit with five amplifiers.

FIG. 13B is a simplified circuit schematic of a capacitor voltage divider of a charge recycling circuit for the output stage of FIG. 13A.

FIG. 14 is a flow diagram illustrating a method for recycling charge.

FIGS. 15A and 15B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Interferometric modulator (IMOD) displays may include a movable element, such as a mirror, that can be positioned at various points in order to reflect light at a specific wavelength. In some implementations, the movable element of the IMOD may be moved to a particular position from a starting point. The movable element may be moved to the particular position from the starting point based on a particular application of voltages to electrodes of the IMOD. The voltages provided to the electrodes may be provided by a driver circuit. The voltage range applied to the electrodes may be large, and therefore, high voltage devices may be used to produce voltages within the range needed to position the movable element. However, high voltage devices may require larger device sizes, and therefore, occupy more area on the silicon die than low voltage devices. A driver providing a large voltage range may also increase power requirements. Some implementations of the subject matter described herein include cascading operational amplifiers providing different voltage ranges. Each amplifier may be coupled with a switch. A single switch may be turned on such that a single amplifier provides a voltage to an electrode of the IMOD. The power supplies of the amplifier may also have overlapping supply voltages. Charge may be recycled among the power supplies.

Particular implementations of the subject matter described in this disclosure can be implemented to realize one or more of the following potential advantages. Using multiple amplifiers with different voltage ranges may allow for low voltage devices to be used, and therefore, less area of the silicon die may be used. Additionally, charge recycling may lower power requirements. Amplifiers may use DC current and dynamic current sinking and sourcing to drive a display.

An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

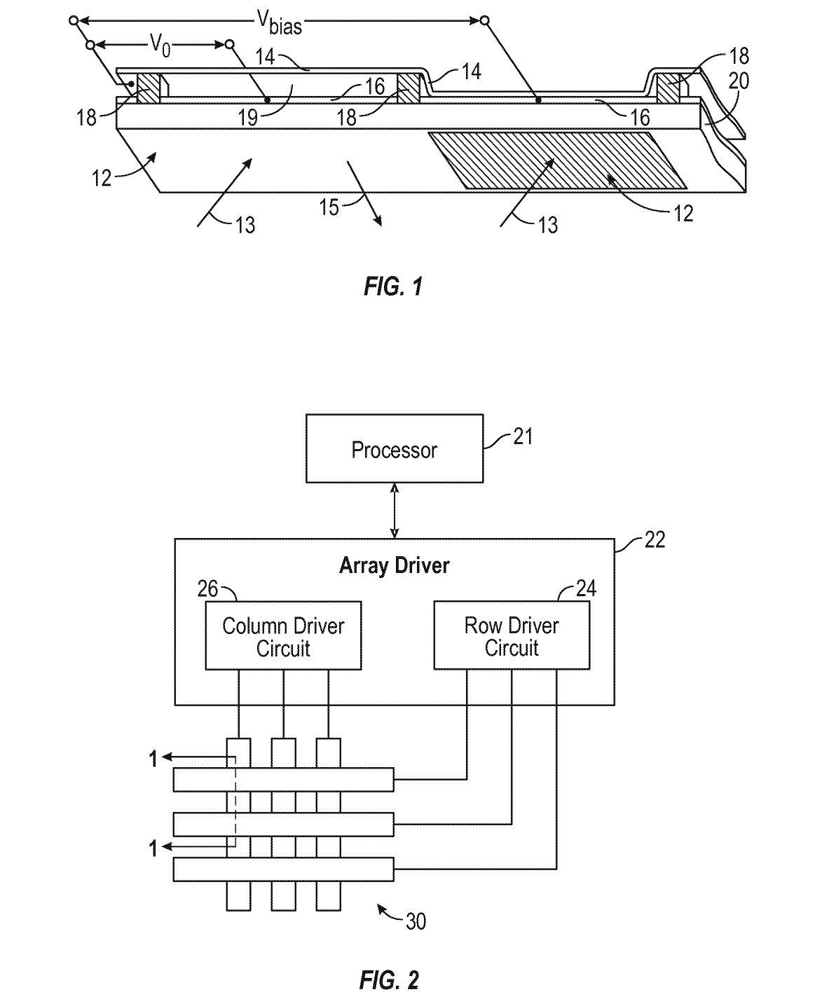

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa.

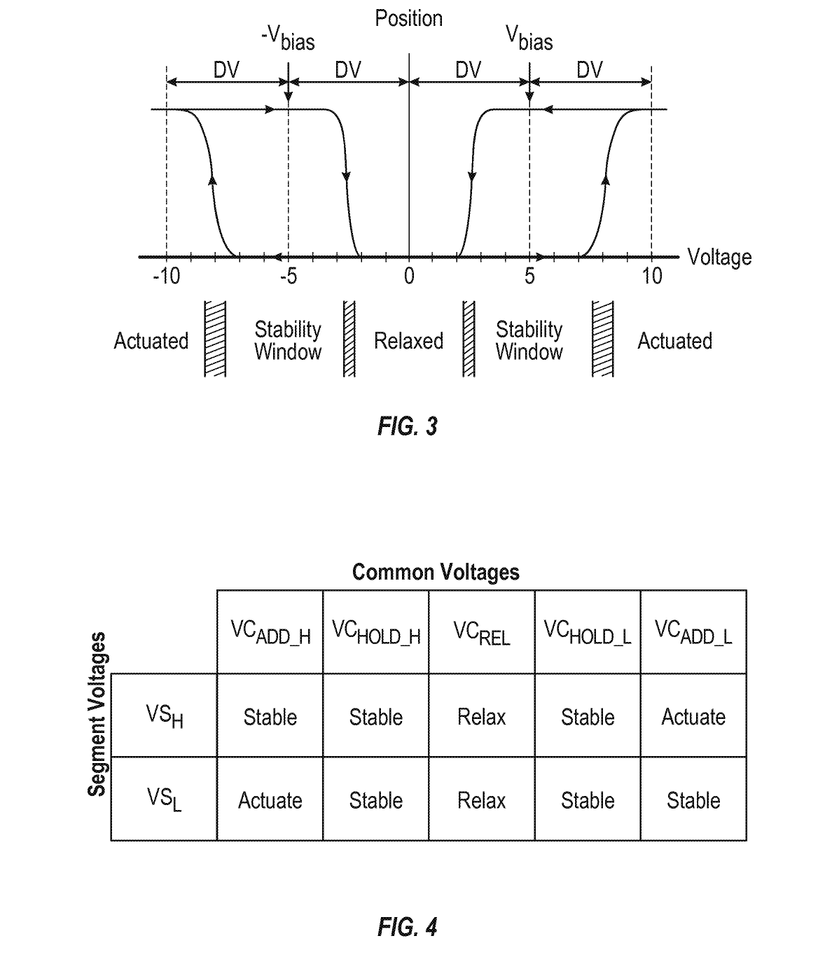

FIG. 3 is a graph illustrating movable reflective layer position versus applied voltage for an IMOD display element. For IMODs, the row/column (i.e., common/segment) write procedure may take advantage of a hysteresis property of the display elements as illustrated in FIG. 3. An IMOD display element may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3-7 volts, in the example of FIG. 3, exists where there is a window of applied voltage within which the element is stable in either the relaxed or actuated state. This is referred to herein as the “hysteresis window” or “stability window.” For a display array 30 having the hysteresis characteristics of FIG. 3, the row/column write procedure can be designed to address one or more rows at a time. Thus, in this example, during the addressing of a given row, display elements that are to be actuated in the addressed row can be exposed to a voltage difference of about 10 volts, and display elements that are to be relaxed can be exposed to a voltage difference of near zero volts. After addressing, the display elements can be exposed to a steady state or bias voltage difference of approximately 5 volts in this example, such that they remain in the previously strobed, or written, state. In this example, after being addressed, each display element sees a potential difference within the “stability window” of about 3-7 volts. This hysteresis property feature enables the IMOD display element design to remain stable in either an actuated or relaxed pre-existing state under the same applied voltage conditions. Since each IMOD display element, whether in the actuated or relaxed state, can serve as a capacitor formed by the fixed and moving reflective layers, this stable state can be held at a steady voltage within the hysteresis window without substantially consuming or losing power. Moreover, essentially little or no current flows into the display element if the applied voltage potential remains substantially fixed.

In some implementations, a frame of an image may be created by applying data signals in the form of “segment” voltages along the set of column electrodes, in accordance with the desired change (if any) to the state of the display elements in a given row. Each row of the array can be addressed in turn, such that the frame is written one row at a time. To write the desired data to the display elements in a first row, segment voltages corresponding to the desired state of the display elements in the first row can be applied on the column electrodes, and a first row pulse in the form of a specific “common” voltage or signal can be applied to the first row electrode. The set of segment voltages can then be changed to correspond to the desired change (if any) to the state of the display elements in the second row, and a second common voltage can be applied to the second row electrode. In some implementations, the display elements in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each display element (that is, the potential difference across each display element or pixel) determines the resulting state of each display element. FIG. 4 is a table illustrating various states of an IMOD display element when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

As illustrated in FIG. 4, when a release voltage VC_{REL} is applied along a common line, all IMOD display elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator display elements or pixels (alternatively referred to as a display element or pixel voltage) can be within the relaxation window (see FIG. 3, also referred to as a release window) both when the high segment voltage VS_{H} and the low segment voltage VS_{L} are applied along the corresponding segment line for that display element.

When a hold voltage is applied on a common line, such as a high hold voltage VC_{HOLD}_{_{—}}_{H} or a low hold voltage VC_{HOLD}_{_{—}}_{L}, the state of the IMOD display element along that common line will remain constant. For example, a relaxed IMOD display element will remain in a relaxed position, and an actuated IMOD display element will remain in an actuated position. The hold voltages can be selected such that the display element voltage will remain within a stability window both when the high segment voltage VS_{H} and the low segment voltage VS_{L} are applied along the corresponding segment line. Thus, the segment voltage swing in this example is the difference between the high VS_{H} and low segment voltage VS_{L}, and is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that common line by application of segment voltages along the respective segment lines. The segment voltages may be selected such that actuation is dependent upon the segment voltage applied. When an addressing voltage is applied along a common line, application of one segment voltage will result in a display element voltage within a stability window, causing the display element to remain unactuated. In contrast, application of the other segment voltage will result in a display element voltage beyond the stability window, resulting in actuation of the display element. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having substantially no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation that could occur after repeated write operations of a single polarity.

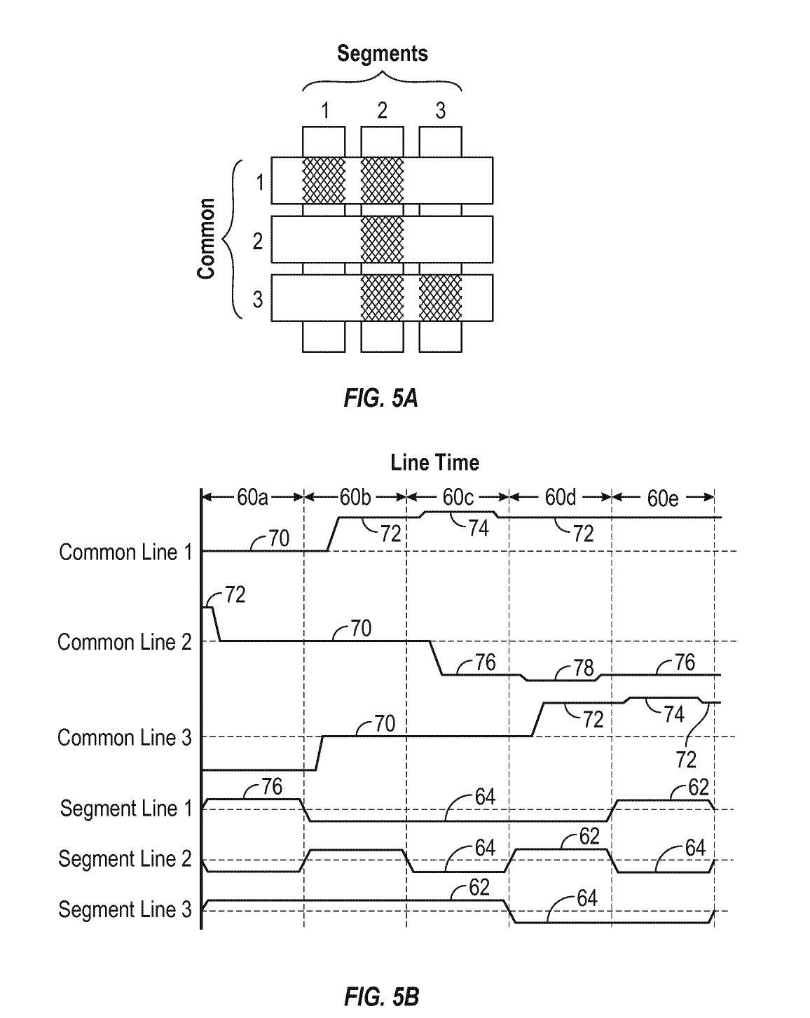

FIG. 5A is an illustration of a frame of display data in a three element by three element array of IMOD display elements displaying an image. FIG. 5B is a timing diagram for common and segment signals that may be used to write data to the display elements illustrated in FIG. 5A. The actuated IMOD display elements in FIG. 5A, shown by darkened checkered patterns, are in a dark-state, i.e., where a substantial portion of the reflected light is outside of the visible spectrum so as to result in a dark appearance to, for example, a viewer. Each of the unactuated IMOD display elements reflect a color corresponding to their interferometric cavity gap heights. Prior to writing the frame illustrated in FIG. 5A, the display elements can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. In some implementations, the segment voltages applied along segment lines 1, 2 and 3 will have no effect on the state of the IMOD display elements, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the display element voltage across modulators (1,1) and (1,2) is greater than the high end of the positive stability window (i.e., the voltage differential exceeded a characteristic threshold) of the modulators, and the modulators (1,1) and (1,2) are actuated. Conversely, because a high segment voltage 62 is applied along segment line 3, the display element voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the display element voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state. Then, the voltage on common line 2 transitions back to the low hold voltage 76.

Finally, during the fifth line time 60e, the voltage on common line 1 remains at high hold voltage 72, and the voltage on common line 2 remains at the low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 display element array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the display element voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5A. In some other implementations, voltages applied along common lines or segment lines may vary to account for variations in the actuation and release voltages of different modulators, such as modulators of different colors.

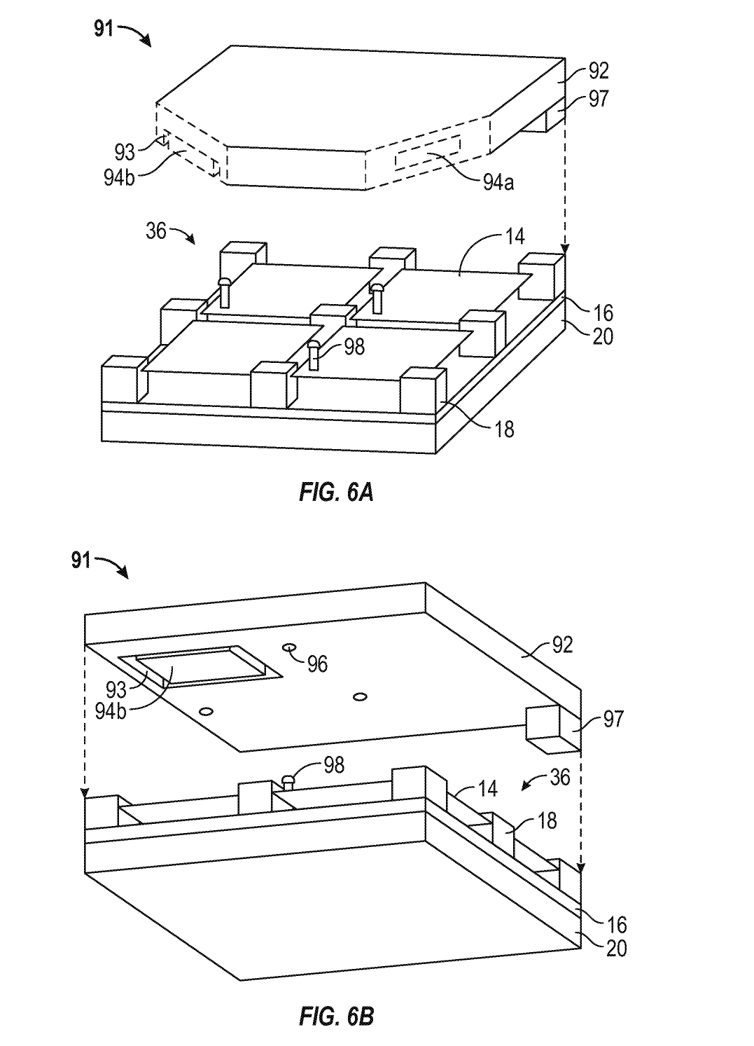

FIGS. 6A and 6B are schematic exploded partial perspective views of a portion of an EMS package 91 including an array 36 of EMS elements and a backplate 92. FIG. 6A is shown with two corners of the backplate 92 cut away to better illustrate certain portions of the backplate 92, while FIG. 6B is shown without the corners cut away. The EMS array 36 can include a substrate 20, support posts 18, and a movable layer 14. In some implementations, the EMS array 36 can include an array of IMOD display elements with one or more optical stack portions 16 on a transparent substrate, and the movable layer 14 can be implemented as a movable reflective layer.

The backplate 92 can be essentially planar or can have at least one contoured surface (e.g., the backplate 92 can be formed with recesses and/or protrusions). The backplate 92 may be made of any suitable material, whether transparent or opaque, conductive or insulating. Suitable materials for the backplate 92 include, but are not limited to, glass, plastic, ceramics, polymers, laminates, metals, metal foils, Kovar and plated Kovar.

As shown in FIGS. 6A and 6B, the backplate 92 can include one or more backplate components 94a and 94b, which can be partially or wholly embedded in the backplate 92. As can be seen in FIG. 6A, backplate component 94a is embedded in the backplate 92. As can be seen in FIGS. 6A and 6B, backplate component 94b is disposed within a recess 93 formed in a surface of the backplate 92. In some implementations, the backplate components 94a and/or 94b can protrude from a surface of the backplate 92. Although backplate component 94b is disposed on the side of the backplate 92 facing the substrate 20, in other implementations, the backplate components can be disposed on the opposite side of the backplate 92.

The backplate components 94a and/or 94b can include one or more active or passive electrical components, such as transistors, capacitors, inductors, resistors, diodes, switches, and/or integrated circuits (ICs) such as a packaged, standard or discrete IC. Other examples of backplate components that can be used in various implementations include antennas, batteries, and sensors such as electrical, touch, optical, or chemical sensors, or thin-film deposited devices.

In some implementations, the backplate components 94a and/or 94b can be in electrical communication with portions of the EMS array 36. Conductive structures such as traces, bumps, posts, or vias may be formed on one or both of the backplate 92 or the substrate 20 and may contact one another or other conductive components to form electrical connections between the EMS array 36 and the backplate components 94a and/or 94b. For example, FIG. 6B includes one or more conductive vias 96 on the backplate 92 which can be aligned with electrical contacts 98 extending upward from the movable layers 14 within the EMS array 36. In some implementations, the backplate 92 also can include one or more insulating layers that electrically insulate the backplate components 94a and/or 94b from other components of the EMS array 36. In some implementations in which the backplate 92 is formed from vapor-permeable materials, an interior surface of backplate 92 can be coated with a vapor barrier (not shown).

The backplate components 94a and 94b can include one or more desiccants which act to absorb any moisture that may enter the EMS package 91. In some implementations, a desiccant (or other moisture absorbing materials, such as a getter) may be provided separately from any other backplate components, for example as a sheet that is mounted to the backplate 92 (or in a recess formed therein) with adhesive. Alternatively, the desiccant may be integrated into the backplate 92. In some other implementations, the desiccant may be applied directly or indirectly over other backplate components, for example by spray-coating, screen printing, or any other suitable method.

In some implementations, the EMS array 36 and/or the backplate 92 can include mechanical standoffs 97 to maintain a distance between the backplate components and the display elements and thereby prevent mechanical interference between those components. In the implementation illustrated in FIGS. 6A and 6B, the mechanical standoffs 97 are formed as posts protruding from the backplate 92 in alignment with the support posts 18 of the EMS array 36. Alternatively or in addition, mechanical standoffs, such as rails or posts, can be provided along the edges of the EMS package 91.

Although not illustrated in FIGS. 6A and 6B, a seal can be provided which partially or completely encircles the EMS array 36. Together with the backplate 92 and the substrate 20, the seal can form a protective cavity enclosing the EMS array 36. The seal may be a semi-hermetic seal, such as a conventional epoxy-based adhesive. In some other implementations, the seal may be a hermetic seal, such as a thin film metal weld or a glass frit. In some other implementations, the seal may include polyisobutylene (PIB), polyurethane, liquid spin-on glass, solder, polymers, plastics, or other materials. In some implementations, a reinforced sealant can be used to form mechanical standoffs.

In alternate implementations, a seal ring may include an extension of either one or both of the backplate 92 or the substrate 20. For example, the seal ring may include a mechanical extension (not shown) of the backplate 92. In some implementations, the seal ring may include a separate member, such as an O-ring or other annular member.

In some implementations, the EMS array 36 and the backplate 92 are separately formed before being attached or coupled together. For example, the edge of the substrate 20 can be attached and sealed to the edge of the backplate 92 as discussed above. Alternatively, the EMS array 36 and the backplate 92 can be formed and joined together as the EMS package 91. In some other implementations, the EMS package 91 can be fabricated in any other suitable manner, such as by forming components of the backplate 92 over the EMS array 36 by deposition.

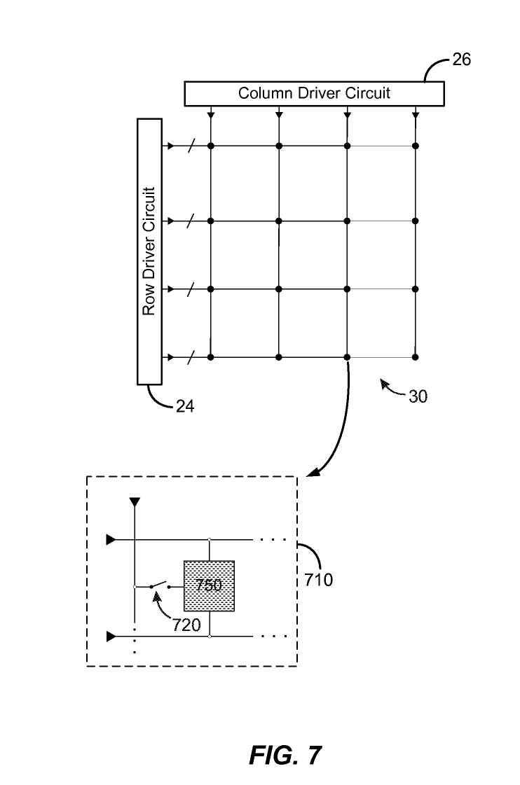

FIG. 7 is an example of a system block diagram illustrating an electronic device incorporating an IMOD-based display. Moreover, FIG. 7 depicts an implementation of row driver circuit 24 and column driver circuit 26 of array driver 22 that provide signals to, for example, display array or panel 30, as previously discussed.

As an example, display module 710 in the fourth row may include switch 720 and display unit 750. Display module 710 may be provided a row signal and a common signal from row driver circuit 24. Display module 710 may also be provided a column signal from column driver circuit 26. The implementation of display module 710 may include a variety of different designs. In some implementations, display unit 750 may be coupled with switch 720, such as a transistor with its gate coupled to the row signal and the column signal provided to the drain. Each display unit 750 may include an IMOD display element as a pixel.

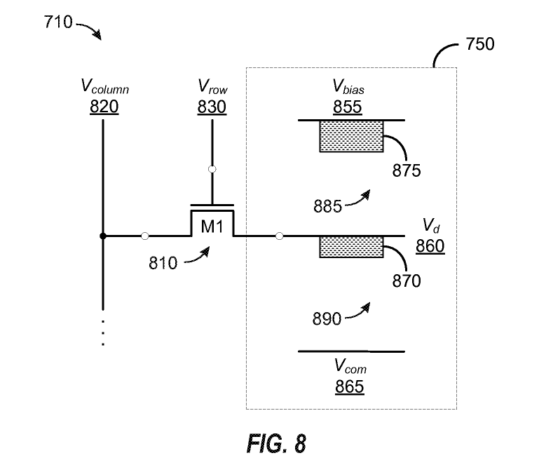

FIG. 8 is a circuit schematic of an example of a three-terminal IMOD. In some implementations, the circuit of FIG. 8 may include display unit 750 (e.g., an IMOD) of FIG. 4. The circuit of FIG. 8 includes switch 720 of FIG. 7 implemented as an n-type metal oxide semiconductor (NMOS) transistor M1 810. The gate of transistor M1 810 is coupled to V_{row} 830, which may be provided by row driver circuit 24 of FIG. 7. Transistor M1 810 is also coupled to V_{column} 820, which may be provided by column driver circuit 26 of FIG. 7. In particular, if V_{row} 830 is biased to turn transistor M1 810 on, the voltage on V_{column} 820 may be applied to V_{d} electrode 860.

In an implementation, display unit 750 may be a three-terminal IMOD including three terminals or electrodes: V_{bias} electrode 855, V_{d} electrode 860, and V_{com} electrode 865. Display unit 750 may also include movable element 870 and dielectric 875. Movable element 870 may include a mirror. Movable element 870 may be coupled with V_{d} electrode 860. Additionally, in some implementations, air gap 885 may be between V_{bias} electrode 855 and V_{d} electrode 860. Air gap 890 may be between V_{d} electrode 860 and V_{com} electrode 865. In some implementations, display unit 750 may also include one or more capacitors. For example, one or more capacitors may be coupled between V_{d} electrode 860 and V_{com} electrode 865 or between V_{bias} electrode 855 and V_{d} electrode 860.

Movable element 870 may be positioned at various points between V_{bias} electrode 855 and V_{com} electrode 865 in order to reflect light at a specific wavelength. In particular, applied voltage biases of V_{bias} electrode 855, V_{d} electrode 860, and V_{com} electrode 865 may determine the position of movable element 870.

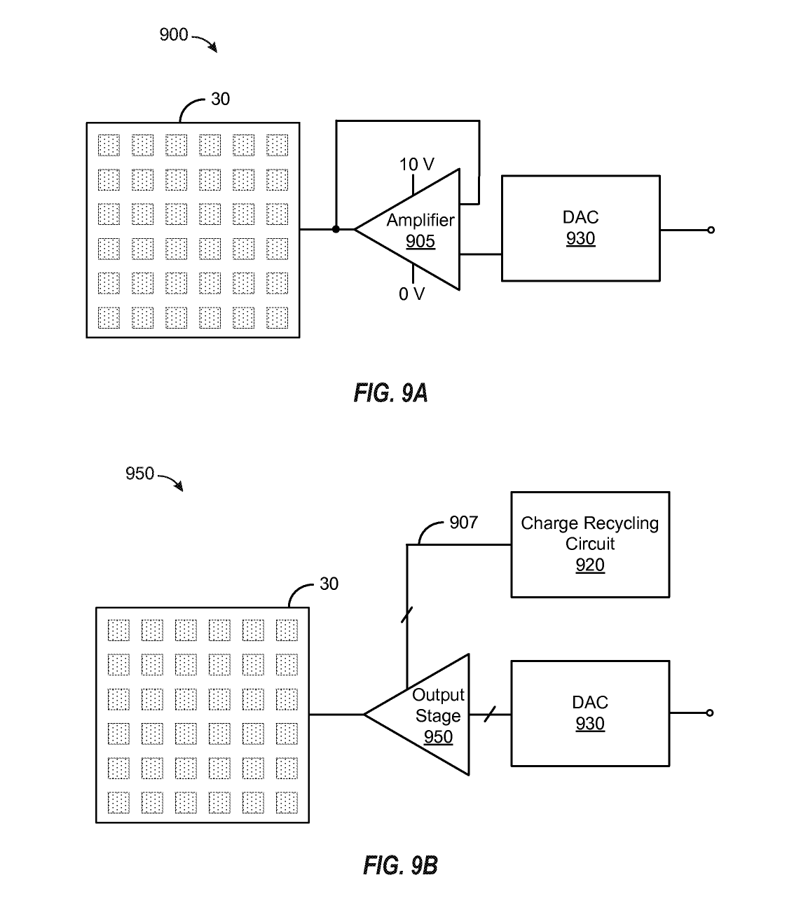

FIG. 9A is an example of a system block diagram illustrating an output stage of a driver circuit. System 900 in FIG. 9A includes amplifier 905 providing a voltage to be applied to V_{bias} electrode 855, V_{d} electrode 860, or V_{com} electrode 865. In some implementations, amplifier 905 may be an operational amplifier (op-amp). For example, amplifier 905 and digital-to-analog converter (DAC) 930 may be implemented in row driver circuit 24 and column driver circuit 26 of array driver 22.

DAC 930 may provide an input to amplifier 905. Other circuitry may provide digital data associated with providing the proper drive voltage to DAC 930, which is then provided to amplifier 905. An output of amplifier 905 is provided as a feedback input to a second input of amplifier 905. The output of amplifier 905 may be provided to a display unit, such as an IMOD, in display array 30. For example, the voltage on the output of amplifier 905 may be provided to any of V_{bias} electrode 855, V_{d} electrode 860, or V_{com} electrode 865. In FIG. 9A, amplifier 905 includes a high power supply of 10 Volts (V) and a low power supply of 0 V in order to provide a voltage range of 0 V to 10 V. Accordingly, based on the output of DAC 930, amplifier 905 may drive an electrode of a display unit 750 from 0 V to 10 V.

As an example, amplifier 905 may provide an output of 10 V. However, when amplifier 905 provides another voltage, current may sink to the low power supply providing 0 V. For example, amplifier 905 in FIG. 9A providing 10 V and switching to 8 V may cause current to sink to the 0 V power supply. As such, the charge is lost and not used elsewhere in system 900. Additionally, because amplifier 905 may have a large voltage range, high voltage devices occupying a large amount of area on the silicon die may be used.

FIG. 9B is an example of a system block diagram illustrating an output stage of a driver circuit with charge recycling. System 950 in FIG. 9B includes output stage 950 providing a voltage to be applied to V_{bias} electrode 855, V_{d} electrode 860, or V_{com} electrode 865. Charge recycling circuit 920 may provide power supplies 907 for driver circuit 910. DAC 930 may provide inputs to output stage 950. Output stage 950, charge recycling unit 920, and DAC 930 may also be implemented in row driver circuit 24 and column driver circuit 26 of array driver 22. Output stage 950 may also provide a voltage range associated with positioning movable element 870 by biasing an electrode of a display unit. For example, output stage 950 may also provide a voltage range of 0 V to 10 V.

In FIG. 9B, charge recycling circuit 920 may recycle charge that would otherwise be lost to a low power supply. For example, if output stage 950 provides a voltage of 10 V and switches to provide an output of 8 V, current may be recycled and reused within system 950, as described below.

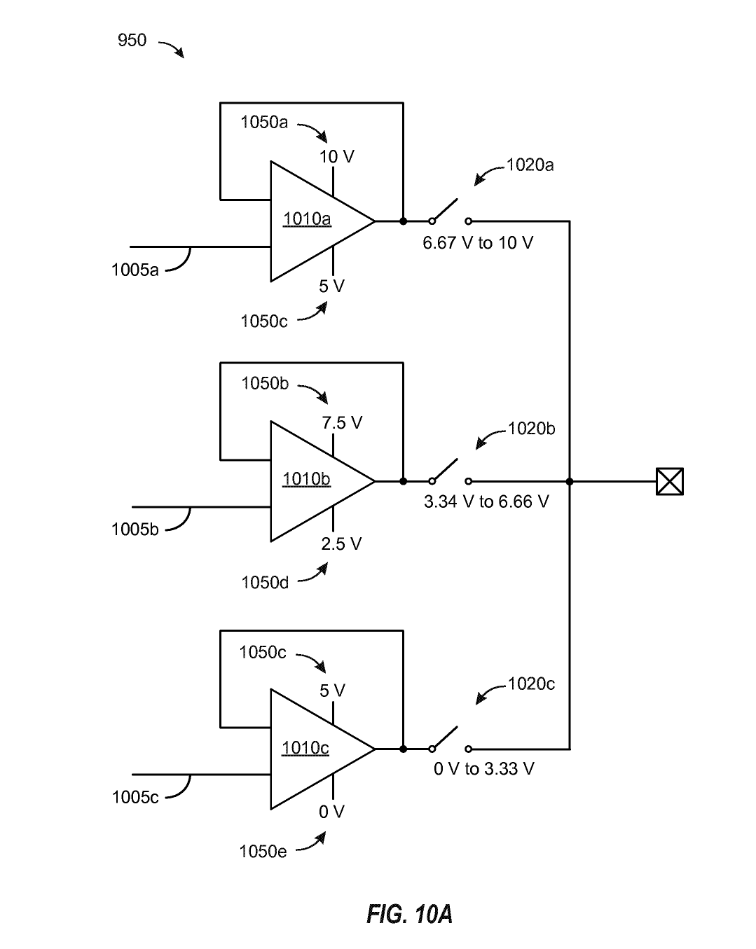

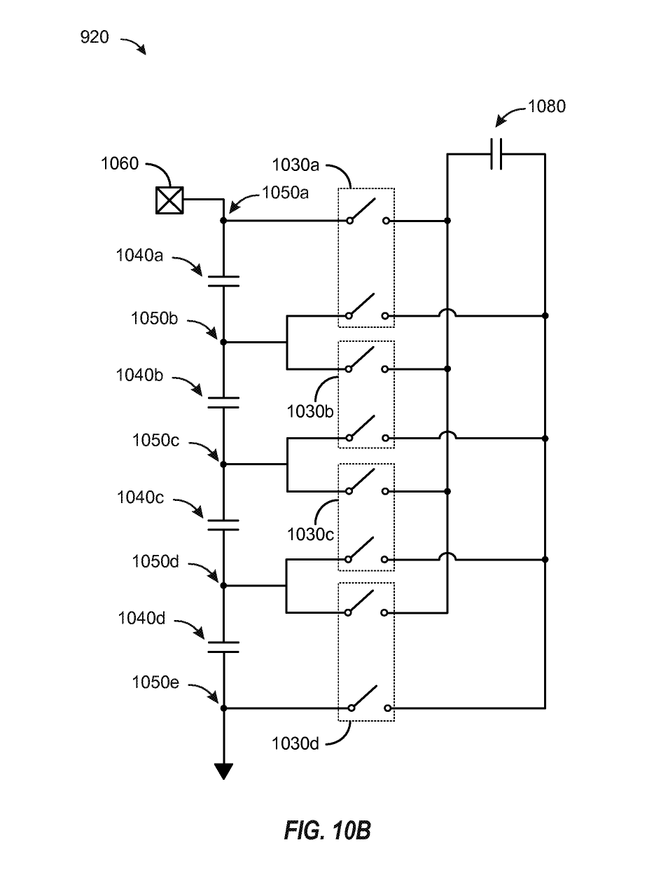

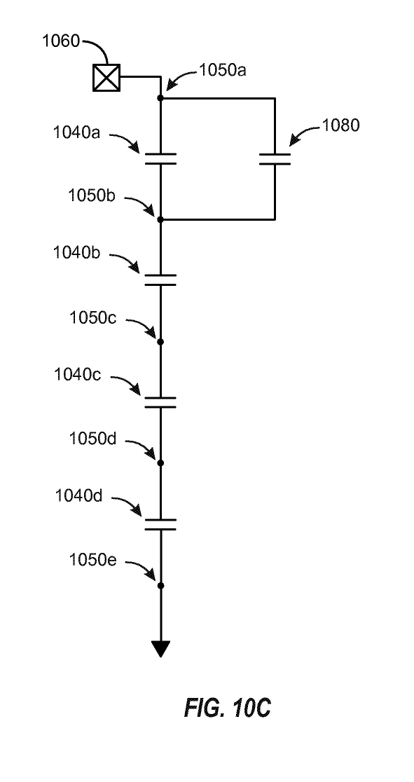

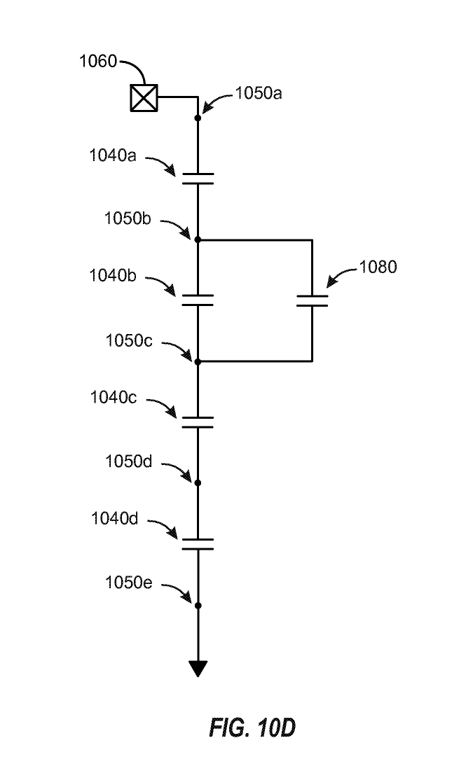

FIG. 10A is a circuit schematic of an example of an output stage of a driver circuit. In FIG. 10A, output stage 950 may provide an output with a voltage range of 0 V to 10 V. However, rather than a single amplifier providing voltages within the entire voltage range, multiple amplifiers 1010a-1010c may provide a voltage within separate smaller voltage ranges. In some implementations, amplifiers 1010a-1010c may be operational amplifiers (op-amps).

In FIG. 10A, amplifier 1010a may provide a voltage within a range of 6.67 V to 10 V. Amplifier 1010b may provide a voltage within a range of 3.34 V to 6.66 V. Amplifier 1010c may provide a voltage within a range of 0 to 3.33 V. Accordingly, the voltage ranges associated with amplifiers 1010a-1010c may together provide a voltage range of 0 V to 10 V, but each individual amplifier 1010a-1010c may provide a smaller voltage range within the larger range. Since each amplifier 1010a-1010c is associated with a smaller voltage range than amplifier 905 of FIG. 9A, low voltage devices may be used to implement amplifier 1010a-1010c, and therefore, save area on the silicon die.

In FIG. 10A, inputs 1005a-1005c may be provided by DAC 930. That is, DAC 930 provides an input to each amplifier 1010a-1010c. Each amplifier 1010a-1010c also includes an output coupled to a switch 1020a-1020c. For example, the output of amplifier 1010a is coupled with switch 1020a. The output of amplifier 1010b is coupled with switch 1020b. The output of amplifier 1010c is coupled with switch 1020c. One of switch 1020a-1020c may be turn on to provide an output of respective amplifiers 1010a-1010c to be provided as an output of output stage 950, and therefore, drive V_{bias} electrode 855, V_{d} electrode 860, or V_{com} electrode 865 of display unit 750. Additionally, the output of each amplifier 1010a-1010c is also provided as a feedback input to the respective amplifier 1010a-1010c. For example, the output of amplifier 1010a is also provided as an input to amplifier 1010a.

Moreover, each of amplifiers 1010a-1010c includes a different set of high power supply inputs and low power supply inputs. For example, amplifier 1010a has a high power supply of 10 V and a low power supply of 5 V. Amplifier 1010b has a high power supply of 7.5 V and a low power supply of 2.5 V. Amplifier 1010c has a high power supply of 5 V and a low power supply of 0 V.

Additionally, the power supplies of amplifier 1010a-1010c may also overlap in voltages. In particular, the low power supply of an amplifier providing a higher voltage range may be lower than the high power supply of an amplifier providing an adjacent and lower voltage range. For example, the low power supply of amplifier 1010a (i.e., 5 V) providing a voltage in the range of 6.67 V to 10 V is less than the high power supply of amplifier 1010b (i.e., 7.5 V) providing a voltage in the adjacent voltage range of 3.34 V to 6.66 V. Likewise, the low power supply of amplifier 1010b (i.e., 2.5 V) providing a voltage in the range of 6.67 V to 10 V is less than the high power supply of amplifier 1010c (i.e., 5 V) providing a voltage in the adjacent voltage range of 0 V to 3.33 V. Accordingly, the voltage of the low power supply of amplifier 1010a providing the highest voltage range is lower than the than the voltage of the high power supply of amplifier 1010b providing the intermediate voltage range. The voltage of the low power supply of amplifier 1010b providing the intermediate voltage range is lower than the voltage of the high power supply of amplifier 1010c providing the lowest voltage range.

Additionally, the power supply voltages for amplifiers 1010a-1010c may step in a uniform increment or magnitude. For example, in the example of FIG. 10A, the power supply voltages step in 2.5 V increments to provide 0 V, 2.5 V, 5 V, 7.5 V, and 10 V.

In an implementation, the high power supply of each amplifier 1010a-1010c increment in uniform increments. For example, the voltage of the high power supply of amplifier 1010a associated with the highest voltage range is 10 V. The voltage of the high power supply of amplifier 1010b associated with the intermediate voltage range is 2.5 V lower (i.e., 7.5 V). Likewise, the voltage of the high power supply of amplifier 1010c associated with the lowest voltage range is 2.5 V lower (i.e., 5 V) than the voltage of the high power supply of amplifier 1010b providing the intermediate voltage range. The low power supplies of amplifiers 1010a-1010c may also increment in uniform increments.

Moreover, in some implementations, a voltage difference between the high power supply and low power supply for each of amplifiers 1010a-1010c may be the same. For example, for amplifier 1010a in FIG. 10A, there is a 5 V difference between the high power supply of 10 V and the low power supply of 5 V. Likewise, there is a 5 V difference for amplifier 1010b with a high power supply of 7.5 V and a low power supply of 2.5 V. Amplifier 1010c also includes a 5 V difference between the high and low power supplies.

FIG. 10B is a circuit schematic of an example of a charge recycling circuit for the output stage of FIG. 10A. In particular, charge recycling circuit 920 in FIG. 10B provides the power supplies for output stage 950 in FIG. 10A. That is, the high and low power supplies amplifiers 1010a-1010c are provided by charge recycling recycling 920.

In FIG. 10B, capacitors 1040a-1040d are coupled in series to form a capacitor voltage divider providing voltage sources for the power supplies of amplifier 1010a-1010c. For example, in FIG. 10B, voltage input 1060 may provide a 10 V input and node 1050e may be biased to 0 V. Accordingly, node 1050a may be biased at 10 V and may provide a voltage source for a high power supply for amplifier 1010a (i.e., the amplifier providing the highest voltage range). Based on the capacitances of capacitors 1040a-1040d being similar, nodes 1050a-1050e may be biased to provide the other voltages sources for power supplies of amplifiers 1010a-1010c. For example, if node 1050a is biased at 10 V by voltage input 1060 and node 1050e is biased at 0V, then node 1050a may provide 10 V, node 1050b may provide 7.5 V, node 1050c may provide 5 V, node 1050d may provide 2.5 V, and node 1050e may provide 0 V because the nodes are part of a capacitor voltage divider. Accordingly, node 1050a may provide a voltage source for a high power supply for amplifier 1010a (i.e., the amplifier providing the high voltage range). For example, node 1010a may be coupled with the high power supply of amplifier 1010a via interconnect. Node 1050b may provide a voltage source for a high power supply for amplifier 1010b (i.e., the amplifier providing an intermediate voltage range). Node 1050c may provide a voltage source for a low power supply for amplifier 1010a (i.e., the amplifier providing the highest voltage range) and a high power supply for amplifier 1010c (i.e., the amplifier providing the lowest voltage range). That is, node 1050c may be biased at 5 V, and therefore, provide both a voltage source low power supply for amplifier 1010a and a high power supply for amplifier 1010c. Node 1050d may provide a voltage source for a low power supply for amplifier 1010b. Node 1050e may provide a voltage source for a low power supply for amplifier 1010c. Accordingly, because nodes 1050a-1050e are associated with the capacitive voltage divider, the nodes are capable of providing a variety of voltage sources.

Additionally, switch pairs 1030a-1030d may turn on one at a time and couple one of capacitors 1040a-1040d to charge pump capacitor 1080. Charge pump capacitor 1080 may act as a storage capacitor for storing excess charge. In particular, charge pump capacitor 1080 may be coupled in parallel with one of capacitors 1040a-1040d when one of switch pairs 1030a-1030d is turned on. In some implementations, capacitors 1040a-1040d and charge pump capacitor 1080 may have capacitances from 1 microfarad (μF) to 10 μF.

FIGS. 10C and 10D are circuit schematics of examples of simplified representations of the charge recycling circuit in FIG. 10B. In FIG. 10C, if the two switches in switch pair 1030a are turned on and the switches in switch pairs 1030b-1030d are turned off, charge pump capacitor 1080 may be coupled in parallel with capacitor 1040a. Likewise, in FIG. 10D, if the two switches in switch pair 1030b are turned on and the switches in switch pairs 1030a, 1030c, and 1030d are turned off, charge pump capacitor 1080 may be coupled in parallel with capacitor 1040b. Switch pairs 1030c and 1030d may also be independently turned on to couple charge pump capacitor 1080 in parallel with capacitors 1040c and 1040d, respectively.

In some implementations, charge pump capacitor 1080 may cycle through being coupled in parallel with each capacitor 1040a-1040d. For example, the switches in switch pair 1030a may turn on, and therefore, couple charge pump capacitor 1080 in parallel with capacitor 1040a. Next, the switches in switch pair 1030a may turn off. Subsequently, the switches in switch pair 1030b may turn on, and therefore, couple charge pump capacitor 1080 in parallel with capacitor 1040b. Next, the switches in switch pair 1030b may turn off, and therefore, charge pump capacitor 1080 is no longer coupled to any of capacitors 1040a-1040d. Subsequently, the switches in switch pair 1030c may turn on, and therefore, couple charge pump capacitor 1080 in parallel with capacitor 1040c. Next, the switches in switch pair 1030c may turn off, followed by the switches in switch pair 1030d turning on, and therefore, coupling charge pump capacitor 1080 in parallel with capacitor 1040d. Next, the switches in switch pair 1030d may turn off, followed by the switches in switch pair 1030a turning on, and therefore, couple charge pump capacitor 1080 again with capacitor 1040a. Accordingly, the switches in switch pairs 1030a-1030d may be cycled to be turned on and couple charge pump capacitor 1080 in parallel with a single one of the capacitors 1040a-1040d. In some implementations, a switch pair may be configured to be on for a time that allows the respective capacitor to be fully recharged by charge pump capacitor 1080.

In some implementations, charge pump capacitor 1080 may store excess charge from capacitors 1040a-1040d when they are coupled in parallel. Additionally, charge pump capacitor 1080 may also recharge capacitors 1040a-1040d when they are coupled in parallel. In general, when charge pump capacitor 1080 is in parallel with one of capacitors 1040a-1040d, charge may flow from the capacitor with higher voltage to the capacitor with lower voltage, as explained below.

For example, if amplifier 1010a in FIG. 10A transitions from providing a voltage of 10 V to 8 V, current may sink to the low power supply (i.e., 5 V provided by node 1050c). When the current sinks to node 1050c, excess charge may accumulate on capacitor 1040c. That is, when current sinks to node 1050c providing 5 V, the voltage on node 1050c may slightly increase to, for example, 5.1 V because excess charge is stored on capacitor 1040c. When the switches in switch pair 1030c turn on, charge pump capacitor 1080 may be coupled in parallel with capacitor 1040c of the capacitive voltage divider, and therefore, the excess charge may be transferred to charge pump capacitor 1080 if capacitor 1040c (i.e., the capacitor providing node 1050c with a slightly increased voltage of 5.1 V) has a higher voltage than charge pump capacitor 1080.

Afterwards, when another switch pair 1030a-1030d turns on, charge pump capacitor 1080 may replenish the charge of a capacitor if it has a lower voltage than charge pump capacitor 1080. For example, if amplifier 1010b transitions from providing a voltage of 4 V to 6 V, current may be drawn from capacitor 1040b, and therefore, charge on capacitor 1040b may be reduced. When the switches in switch pair 1030b are turned on, charge associated with capacitor 1040b may be replenished by charge pump capacitor 1080. Accordingly, charge may be transferred from one capacitor to another to store or replenish charge. That is, charge may be transferred from capacitors 1040a-1040d to charge pump capacitor 1080 to store charge, and transferred from charge pump capacitor 1080 to capacitors 1040a-1040d to replenish charge. As such, charge may be recycled to provide lower power usage.

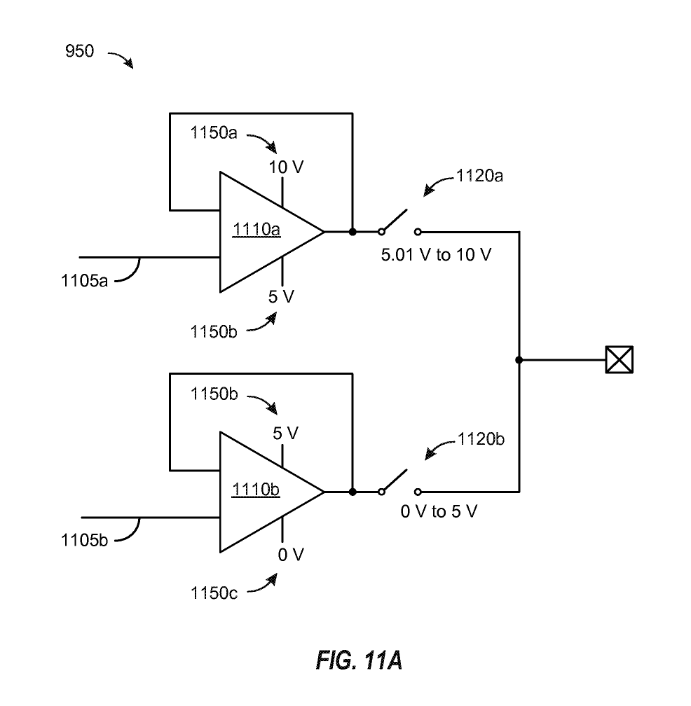

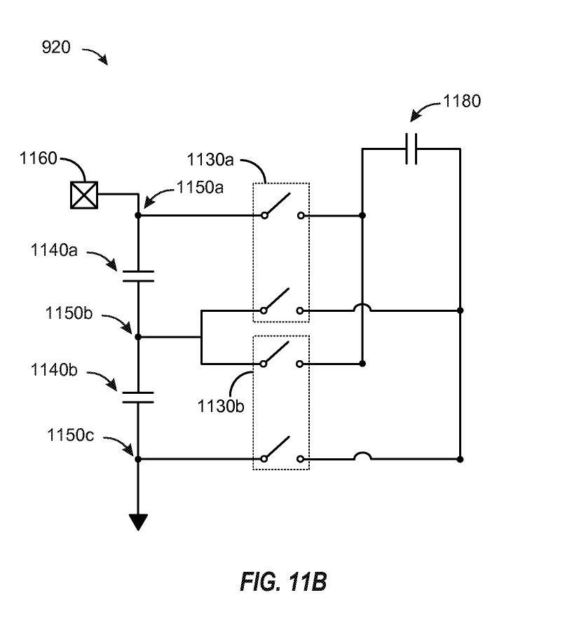

Any number of amplifiers may be cascaded together in an output stage to provide any voltage range. Likewise, any number of switch pairs and capacitors may be used to provide charge recycling circuitry for an output stage. For example, FIG. 11A is a circuit schematic of an example of an output stage of a driver circuit. Output stage 920 in FIG. 11A includes two amplifiers 1110a and 1110b. Amplifier 1110a may provide a voltage range of 5.01 V to 10 V. Amplifier 1110b may provide a voltage range of 0 V to 5 V. Amplifier 1110a may have a high power supply of 10 V and a low power supply of 5 V. Amplifier 1110b may have a high power supply of 5 V and a low power supply of 0 V.

FIG. 11B is a circuit schematic of an example of a charge recycling circuitry for the output stage of FIG. 11A. Capacitors 1140a and 1140b may also be coupled in series to provide a capacitive voltage divider. Therefore, nodes 1150a, 1150b, and 1150c may provide voltage sources for power supplies for amplifiers 1110a and 1110b. For example, if voltage input 1160 is about 10 V and node 1150c is biased at 0 V, node 1150a may be biased at about 10 V, and therefore, provide a voltage source for a high voltage supply for amplifier 1110a. If node 1150a is at about 10 V, then node 1150b may be biased at about 5 V. As such, node 1150b may provide the low power supply of amplifier 1110a and the high power supply of amplifier 1110b. Lastly, if node 1150b is biased at about 5 V, then node 1150c may be biased at 0 V and provide a voltage source for a low power supply for amplifier 1110b.

Similar to the charge recycling unit of FIG. 10B, switches in switch pairs 1130a and 1130b couple charge pump capacitor 1180 in parallel with one of capacitors 1140a and 1140b. Accordingly, excess charge may be stored on capacitor 1180 and charge may be replenished on capacitors 1140a and 1140b.

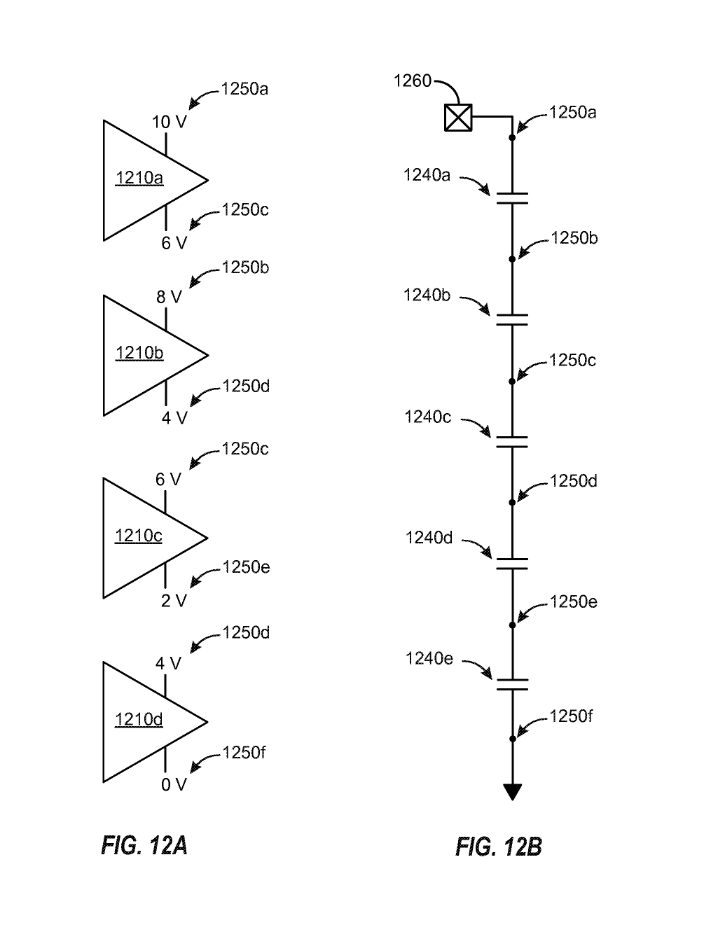

FIG. 12A is a simplified illustration of power supplies for an output stage of a driver circuit with four amplifiers. FIG. 12B is a simplified circuit schematic of a capacitor voltage divider of a charge recycling circuit for the output stage of FIG. 12A. In FIG. 12A, four amplifiers 1210a-1210d may provide voltage ranges within a full voltage range, for example, of 0 V to 10 V. The capacitor voltage divider in FIG. 12B may include five capacitors 1240a-1240e. If voltage input 1260 is biased about 10 V and node 1250f is biased about 0 V, and capacitors 1240a-1240e have similar capacitances, then voltages of about 10 V, 8 V, 6 V, 4 V, 2V, and 0 V may be provided as voltage sources associated with node 1250a, node 1250b, node 1250c, node 1250d, node 1250e, and node 1250f, respectively. The voltage sources may be provided as high and low power supplies of amplifiers 1210a-1210d in FIG. 12A.

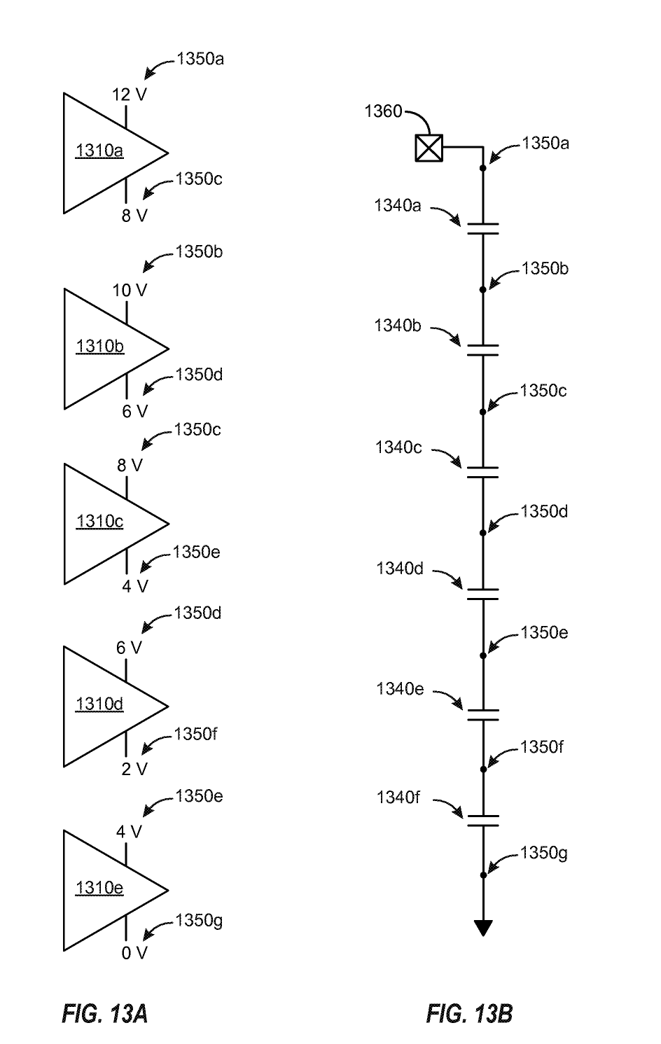

FIG. 13A is a simplified illustration of power supplies for an output stage of a driver circuit with five amplifiers. FIG. 13B is a simplified circuit schematic of a capacitor voltage divider of a charge recycling circuit for the output stage of FIG. 13A. In FIG. 13A, five amplifiers 1310a-1310e may provide voltage ranges within a full voltage range, for example, of 0 V to 12 V. The capacitor voltage divider in FIG. 13B may include six capacitors 1340a-1340f. In FIG. 13B, if voltage input 1360 provides about 12 V and node 1350g is biased about 0 V, and capacitors 1340a-1340f have similar capacitances, then voltages of about 12 V, 10 V, 8 V, 6 V, 4 V, 2 V, and 0 V may be provided as voltage sources associated with node 1350a, node 1350b, node 1350c, node 1350d, node 1350e, node 1350f, and node 1250g, respectively. The voltage sources may be provided as high and low power supplies of amplifiers 1310a-1310e in FIG. 13A.

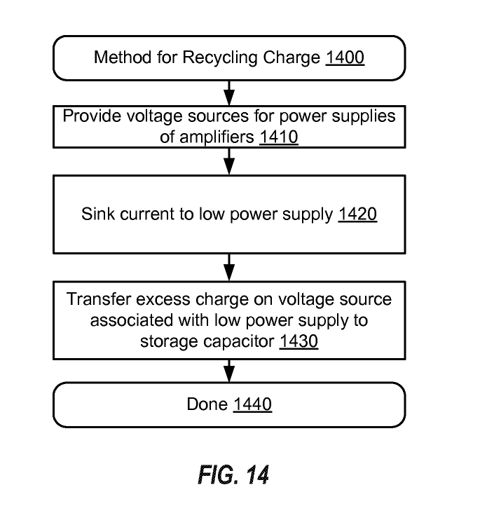

FIG. 14 is a flow diagram illustrating a method for recycling charge. In method 1400, at block 1410, voltage sources for high and low power supplies of amplifiers may be provided. For example, a voltage input may be provided as an input to a charge recycling unit. The voltage on the voltage input may be divided by a capacitive voltage divider to provide high and low power supplies for each amplifier. At block 1420, current may be sunk to the low power supply of an amplifier. For example, if an amplifier transitions to output a lower voltage, current may be sent to the low power supply of the amplifier. In block 1430, excess charge sent to the voltage source providing the low power supply may be transferred to a storage capacitor for storage. The method is done at block 1440.

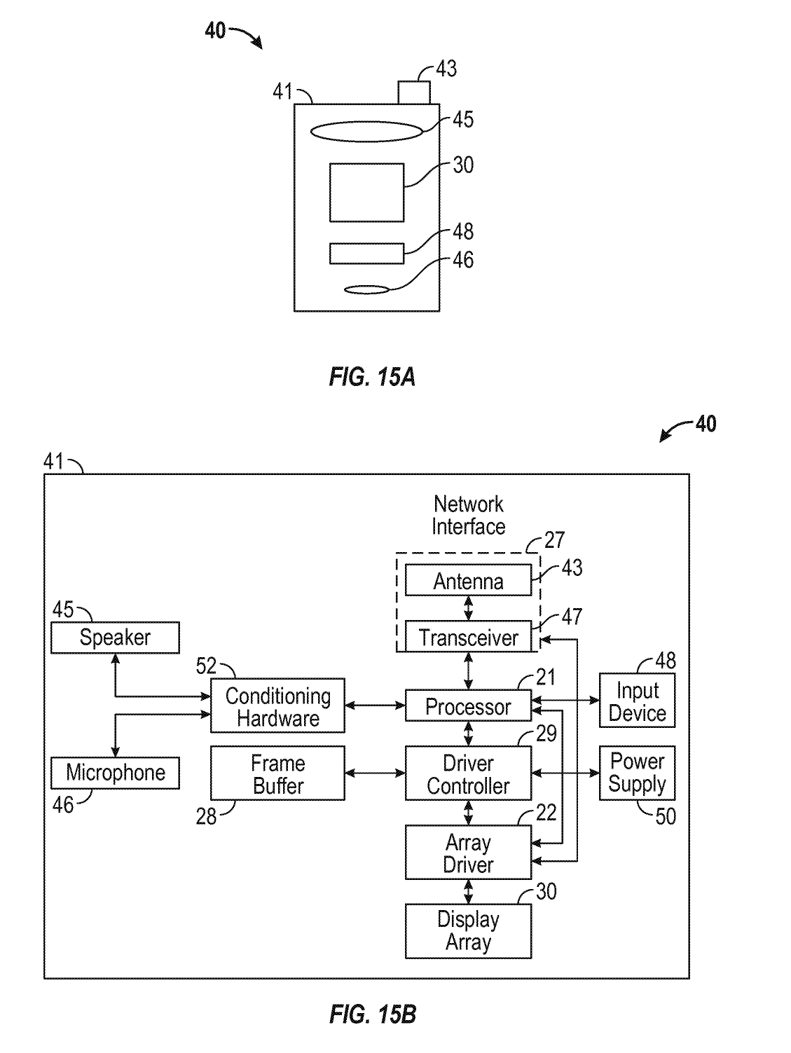

FIGS. 15A and 15B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 15A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 15A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

The circuits and techniques disclosed herein utilize examples of values (e.g., voltages, capacitances, dimensions, etc.) that are provided for illustration purposes only. Other implementations may involve different values.

What is claimed is:

1. A circuit for driving an electrode of a display unit, the circuit comprising:
a first amplifier, an output of the first amplifier being coupled with a first terminal of a first switch, the output of the first amplifier capable of providing a voltage in a first voltage range, the first amplifier having a high power supply input associated with a first voltage source and a low power supply input associated with a second voltage source; and
a second amplifier, an output of the second amplifier being coupled with a first terminal of a second switch, the output of the second amplifier capable of providing a voltage in a second voltage range different from the first voltage range, a second terminal of the first switch being coupled with a second terminal of the second switch, the second amplifier having a high power supply input associated with the second voltage source and a low power supply input associated with a third voltage source.

2. The circuit of claim 1, wherein the first and second amplifiers are operational amplifiers.

3. The circuit of claim 1, further comprising:
a capacitor voltage divider including a plurality of capacitors coupled in series to define nodes, the nodes capable of providing the first, second, and third voltage sources for the first amplifier and the second amplifier, respectively.

4. The circuit of claim 3, wherein the capacitor voltage divider includes a first capacitor having a first terminal coupled with a first voltage input to define a first node, the first node capable of providing the first voltage source.

5. The circuit of claim 3, further comprising:
a storage capacitor coupled in parallel with one of the plurality of capacitors in the capacitor voltage divider.

6. The circuit of claim 1, wherein the first voltage source is configured to provide a higher voltage than the second voltage source.

7. The circuit of claim 6, wherein the second voltage source is configured to provide a higher voltage than the third voltage source.

8. The circuit of claim 1, wherein a highest voltage of the second voltage range is less than a lowest voltage of the first voltage range.

9. The circuit of claim 1, wherein a voltage difference between voltages capable of being provided by the first voltage source and the second voltage source is equal to a voltage difference between voltages capable of being provided by the second voltage source and the third voltage source.

10. The circuit of claim 1, wherein the first amplifier has a first input, the output of the first amplifier coupled with the first input of the first amplifier, and the second amplifier has a first input, the output of the second amplifier coupled with the first input of the second amplifier.

11. The circuit of claim 1, further comprising:
a third amplifier, an output of the third amplifier being coupled with a first terminal of a third switch, the output of the third amplifier capable of providing a voltage in a third voltage range, the third amplifier having a high power supply input associated with a fourth voltage source and a low power supply input associated with a fifth voltage source, and wherein a second terminal of the third switch is coupled with the second terminal of the first switch and the second switch.

12. The circuit of claim 11, wherein the second voltage source is capable of providing a lower voltage than the fourth voltage source.

13. The circuit of claim 1, further comprising:
a display including an array of display units;
a processor configured to communicate with the display, the processor being configured to process image data; and
a memory device that is configured to communicate with the processor.

14. The circuit of claim 13, further comprising:
a driver circuit configured to send at least one signal to the display; and
a controller configured to send at least a portion of the image data to the driver circuit.

15. The circuit of claim 13, further comprising:
an image source module configured to send the image data to the processor, wherein the image source module comprises at least one of a receiver, transceiver, and transmitter.

16. The circuit of claim 13, further comprising:
an input device configured to receive input data and to communicate the input data to the processor.

17. A system for biasing an electrode of a display unit, the system comprising:
an output stage including a plurality of amplifiers, each amplifier having a high power supply input and a low power supply input; and
a charge recycling circuit including a capacitor voltage divider, the capacitor voltage divider including a plurality of capacitors coupled in series to define nodes, the nodes capable of providing voltage sources for the high power supply inputs and the low power supply inputs of the amplifiers.

18. The system of claim 17, wherein the plurality of amplifiers in the output stage includes:
a first amplifier, an output of the first amplifier being coupled with a first terminal of a first switch, the output of the first amplifier capable of providing a voltage in a first voltage range, the first amplifier having a high power supply input associated with a first voltage source and a low power supply input associated with a second voltage source; and
a second amplifier, an output of the second amplifier being coupled with a first terminal of a second switch, the output of the second amplifier capable of providing a voltage in a second voltage range different from the first voltage range, a second terminal of the first switch being coupled with a second terminal of the second switch, the second amplifier having a high power supply input associated with the second voltage source and a low power supply input associated with a third voltage source.

19. The system of claim 17, further comprising:
a storage capacitor coupled in parallel with one of the plurality of capacitors in the capacitor voltage divider.

20. A method for recycling charge, the method comprising:
providing voltage sources for power supplies of a plurality of amplifiers, wherein the plurality of amplifiers includes:
a first amplifier, an output of the first amplifier being coupled with a first terminal of a first switch, the output of the first amplifier capable of providing a voltage in a first voltage range, the first amplifier having a high power supply input associated with a first voltage source and a low power supply input associated with a second voltage source; and
a second amplifier, an output of the second amplifier being coupled with a first terminal of a second switch, the output of the second amplifier capable of providing a voltage in a second voltage range different from the first voltage range, a second terminal of the first switch being coupled with a second terminal of the second switch, the second amplifier having a high power supply input associated with the second voltage source and a low power supply input associated with a third voltage source;
sinking current to a low power supply of one of the plurality of amplifiers; and
transferring excess charge on the low power supply to a storage capacitor.

21. The method of claim 20, further comprising:
providing a capacitor voltage divider including a plurality of capacitors coupled in series to define nodes, the nodes providing the voltage sources for the first amplifier and the second amplifier.
